(19) United States
(12) Patent Application Publication
(10) Pub. No.: US 2009/0033439 A1
(43) Pub. Date: Feb. 5, 2009

(54) MULTILAYER FILTER

(75) Inventor: Tomohiro Igarashi, Tokyo (JP)

Correspondence Address: LOWE HAUPTMAN HAM & BERNER, LLP, 1700 DIAGONAL ROAD, SUITE 300, ALEXANDRIA, VA, 22314, US

(73) Assignee: Taiyo Yuden Co., Ltd., Tokyo (JP)

(21) Appl. No.: 11/813,776

(22) PCT Filed: Jun. 13, 2006
(86) PCT No.: PCT/JP2006/311834

§ 371 Date: Jul. 12, 2007

(30) Foreign Application Priority Data
Jun. 13, 2005 (JP) 2005-172543

(51) Int. Cl. H03H 7/01

(52) U.S. Cl. 333/185

(57) ABSTRACT

A multilayer filter wherein the capacitances of capacitors are reduced to reduce the size of the filter without substantially affecting the filter frequency characteristics. A predetermined filter circuit includes plural electrodes in a dielectric ceramic device body. Each of the capacitors is respectively disposed at input and output ends of the filter circuit and has one end connected to one of input/output terminals. Winding-type inductors, interposed between the input/output terminals and the one ends of the capacitors, are in the device body.

### RELATED APPLICATIONS

The present application is based on, and claims priority from, Japanese Application Number 2005-172543, filed Jun. 13, 2005 and International Application No. PCT/JP06/311834, filed Jun. 13, 2006 the disclosures of which are hereby incorporated by reference herein in their entirety.

### TECHNICAL FIELD

The present invention relates to a multilayer filter used in a high-frequency region.

### BACKGROUND ART

In recent years, with the widespread use of small communication devices such as portable telephones, the use of a dielectric-multilayer filter (hereinafter referred to as “multilayer filter”) such as one disclosed in Japanese Patent No. 3197249 (Patent Document 1) has increased. FIG. 8 is a perspective view of a dielectric multilayer filter of this kind. FIG. 9 is an exploded perspective view of the construction of internal electrodes of the dielectric multilayer filter of FIG. 9. FIG. 10 is an equivalent circuit diagram of the filter of FIG. 9. The multilayer filter 2 shown in these figures is basically a high-pass filter (hereinafter referred to as “HPF”) having a characteristic as to cause steep attenuation at a particular frequency by means of an LC resonance circuit. A filter having such a characteristic is also generally called a notch filter.

The multilayer filter 2 shown in FIG. 8 includes strip line electrodes and capacitor electrodes in a plurality of layers in a device body in the form of a rectangular block not shown in the figures, the device body being made of a low temperature co-fired ceramic (LTCC), and by connecting the electrodes in the different layers through via conductors at predetermined positions.

That is, the multilayer filter 2 has electrodes disposed in the layers from the first layer in the upper most position to the sixth layer in the lowermost position in the device body. GND electrodes (ground electrodes) 601 and 611 are disposed in the first layer in the uppermost position and the sixth layer in the lowermost position. An electrode 602 having two end portions formed as capacitor electrodes 602a and 602b is disposed in the second layer. Two electrodes 603 and 604 are disposed in the third layer. One end portion of the electrode 603 forms a capacitor electrode 603a, and another end portion of the electrode 603 forms a strip line electrode 603b in loop form. Similarly, one end portion of the electrode 604 forms a capacitor electrode 604a, and another end portion of the electrode 604 forms a strip line electrode 604b in loop form. Also, the capacitor electrode 603a is disposed in such a position as to be opposed to the capacitor electrode 602a in the second layer, and the capacitor electrodes 603a and 602a opposed to each other form a capacitor 904. Further, the capacitor electrode 604a is disposed in such a position as to be opposed to the capacitor electrode 602b in the second layer, and the capacitor electrodes 604a and 602b opposed to each other form a capacitor 905.

Four electrodes 605, 606, 607, and 608 are disposed in the fourth layer. The electrode 605 is a strip line electrode in loop form disposed so as to be superposed on the strip line electrode 603b in the third layer. One end 605a of the electrode 605 is connected to the open end of the strip line electrode 603b by a via conductor 711. These strip line electrodes 603b and 605 form a coil (inductor) 901. The electrode 606 is a strip line electrode in loop form disposed so as to be superposed on the strip line electrode 604b in the third layer. One end 606a of the electrode 606 is connected to the open end of the strip line electrode 604b by a via conductor 712. These strip line electrodes 604b and 606 form a coil (inductor) 902.

The electrode 607 is a rectangular capacitor electrode having a projection 607a forming an input terminal 801 at its one side. The electrode 607 is disposed in such as position as to be opposed to the capacitor electrode 603a in the third layer. These capacitor electrodes 607 and 603a opposed to each other form a capacitor 903. The electrode 608 is a rectangular capacitor electrode having a projection 608a forming an input terminal 802 at its one side. The electrode 608 is disposed in such as position as to be opposed to the capacitor electrode 604a in the third layer. These capacitor electrodes 608 and 604a opposed to each other form a capacitor 906.

In the fifth layer, two electrodes 609 and 610 are disposed. The electrode 609 is a rectangular capacitor electrode disposed under the strip line electrode 605 in the fourth layer and connected to the other end of the strip line electrode 605 by a via conductor 713. The capacitor electrode 609 and the GND electrode 611 in the sixth layer form a capacitor 907. The electrode 610 is a rectangular capacitor electrode disposed under the strip line electrode 606 in the fourth layer and connected to the other end of the strip line electrode 606 by a via conductor 714. The capacitor electrode 610 and the GND electrode 611 in the sixth layer form a capacitor 908.

The GND electrodes 601 and 611 in the uppermost and lowermost layers have a shielding function to block the influence of external electromagnetic waves for example.

Patent Document 1: Japanese Patent No. 3197249

### DISCLOSURE OF THE INVENTION

### Problems to be Solved by the Invention

In the above-described conventional multilayer filter 2, however, the constants of the capacitors 903 to 906 are determined, for example, by the dielectric constant and permeability of the ceramic forming the device body and the conductivity and electrical characteristics of the electrodes and, therefore, certain lower limit values exist in the distances between the capacitor electrodes and the areas of the capacitor electrodes. Accordingly, certain lower limit values exist in the inter-electrode distances and areas of the capacitor electrodes 602a, 602b, 603a, 604a, 607, and 608 forming the capacitors 903 to 906. This is a hindrance to reducing the size of the filter.

The GND electrodes 601 and 611 are indispensable for reducing the influence of external noise or the like. However, if the size of the multilayer filter 2 is reduced in thickness in the state where the GND electrodes 601 and 611 exist, parasitic capacitances C1p, C2p, C3p, and C4p that are undesirable for the multilayer filter 2 are formed between the capacitor electrodes 602a, 602b, 609, and 610 and the GND electrodes 601 and 611, as shown in FIG. 11. Thus, there is a hindrance to the reduction in size in thickness. The parasitic capacitance C1p is a parasitic capacitance formed between the capacitor electrode 607 and the GND electrode 611; the parasitic capacitance C2p is a parasitic capacitance formed between the capacitor electrode 602a and the GND electrode 601; the parasitic capacitance C3p is a parasitic capacitance formed between the capacitor electrode 602b and the GND electrode 601; and the parasitic capacitance C4p is a parasitic capacitance formed between the capacitor electrode 610 and the GND electrode 611.

The present invention has been conceived in view of the above-described problems, and an object of the present invention is to provide a multilayer filter capable of reducing the capacitances of capacitors and reducing the size of the filter while maintaining substantially the same frequency characteristics.

### Means for Solving the Problems

To achieve the above-described object, according to the present invention, there is provided a multilayer filter in which a predetermined filter circuit includes a plurality of electrodes in a device body made of a dielectric ceramic. Each of the capacitors is respectively disposed at input and output ends of the filter circuit and has one end connected to one of two input/output terminals. Inductors are interposed between the input/output terminals and the one ends of the capacitors in the device body.

Reactances in the desired frequency pass band become resultant reactances of the reactances of the capacitors and the reactances of the inductors as a result of addition of the impedances of inductors with respect to the negative reactances in the desired frequency pass band in the state before addition of the inductors. Therefore, a filter having equivalent frequency characteristics can be formed by using capacitors having capacitances smaller than those of the above-described capacitors.

### Advantages of the Invention

In the multilayer filter of the present invention, the capacitances of the capacitors connected to the input/output terminals are less than those in the conventional arrangement to enable the device body to be reduced in size. Moreover, the inductors connected to the input/output terminals cause a reduction in the parasitic capacitances compared to the parasitic capacitances of the conventional arrangement. Thus, the present invention has remarkable advantages.

### BRIEF DESCRIPTION OF THE DRAWINGS

FIG. 1 is a see-through perspective view of a multilayer filter in an embodiment of the present invention;

FIG. 2 is an exploded perspective view of the electrode construction of the multilayer filter in the embodiment of FIG. 1;

FIG. 3 is an equivalent circuit diagram of an electrical circuit of the multilayer filter in the embodiment of FIG. 1;

FIG. 4 is a plan view of the multilayer filter in the embodiment of FIG. 1;

FIG. 5 is a diagram of the electrical characteristics of the multilayer filter in the embodiment of FIG. 1;

FIG. 6 is a diagram of the physical appearance of an electronic component in the embodiment of FIG. 1;

FIG. 7 is a block diagram of an example any application of the electronic component in the embodiment of FIG. 1;

FIG. 8 is a perspective view of the disposition of electrodes in a conventional multilayer filter;

FIG. 9 is an exploded perspective view of the construction of the electrodes of the conventional multilayer filter of FIG. 8;

FIG. 10 is an equivalent circuit diagram of an electrical system circuit in the conventional multilayer filter of FIG. 8; and

FIG. 11 is a diagram helpful in explaining parasitic capacitances produced in the conventional multilayer filter of FIG. 8.

### DESCRIPTION OF SYMBOLS

1 Multilayer filter

20 Electronic component

30 Communication function unit

31 IC

32 Capacitor

33 Resistor

41 Antenna

42 CDMA interface

43 Base band signal processing IC

100 Device body

101 Output terminal electrode

102,151,161 GND electrode

111, 112, 121-123, 131-134, 144 Strip line electrode

113 Electrode

113a Strip line electrode

113b Capacitor electrode

114,125-128, 135-137, 145-147, 153, 162, 163, 172, 173 Via conductor

124, 143 Capacitor electrode

141, 142 Electrode

141a, 142a Strip line electrode

141b, 142b Capacitor electrode

152 Electrode

152a Strip line electrode

152b Capacitor electrode

171 GND terminal electrode

173 Input terminal electrode

175 Dummy electrode

201 Input terminal

202 Output terminal

301-304 Inductor

401-406 Capacitor

501-504 Parasitic capacitance

BEST MODE FOR CARRYING OUT THE INVENTION

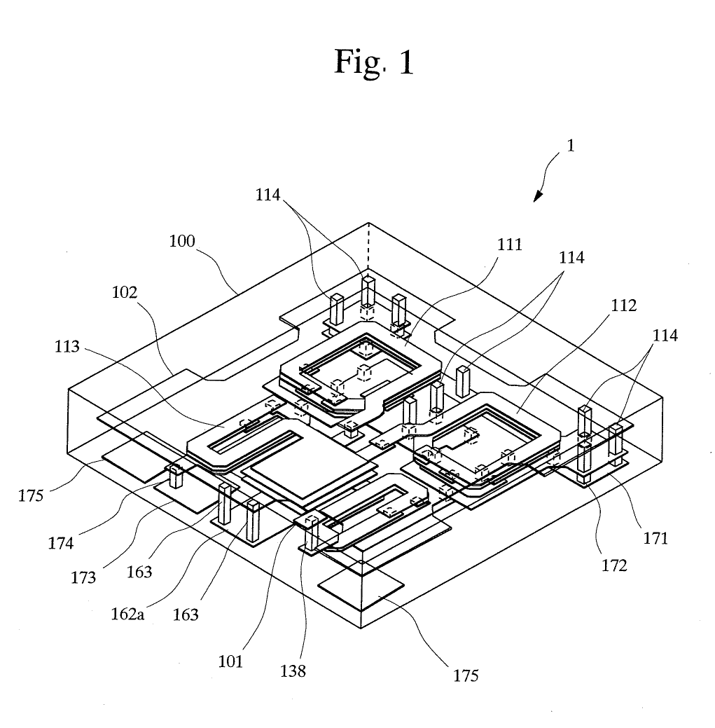

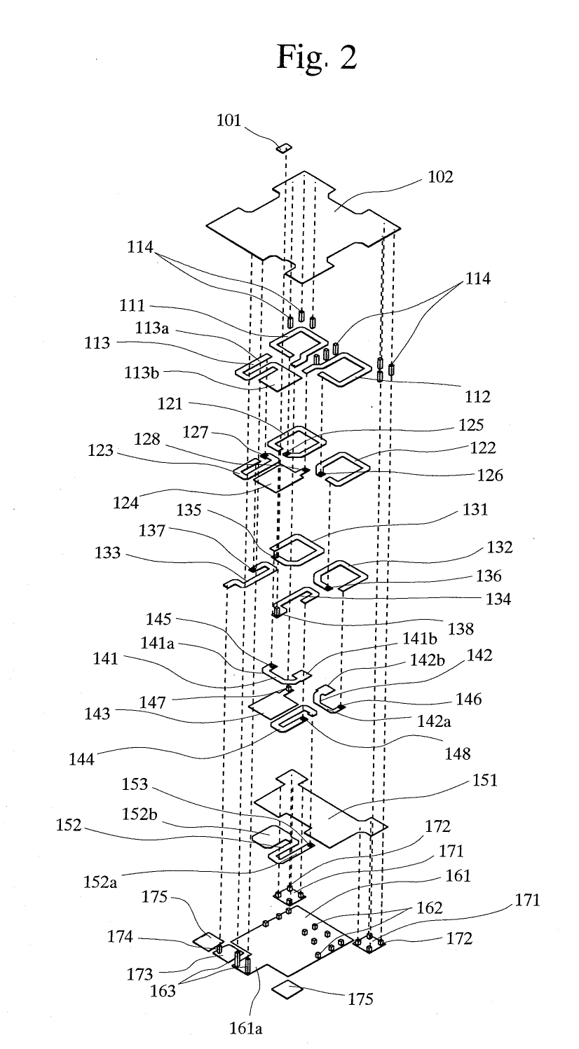

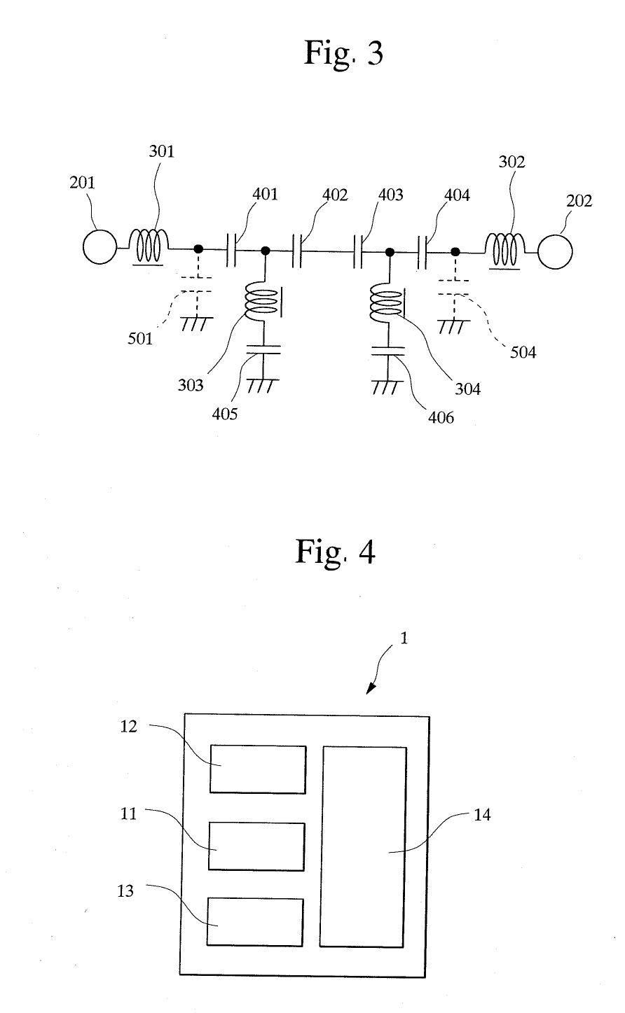

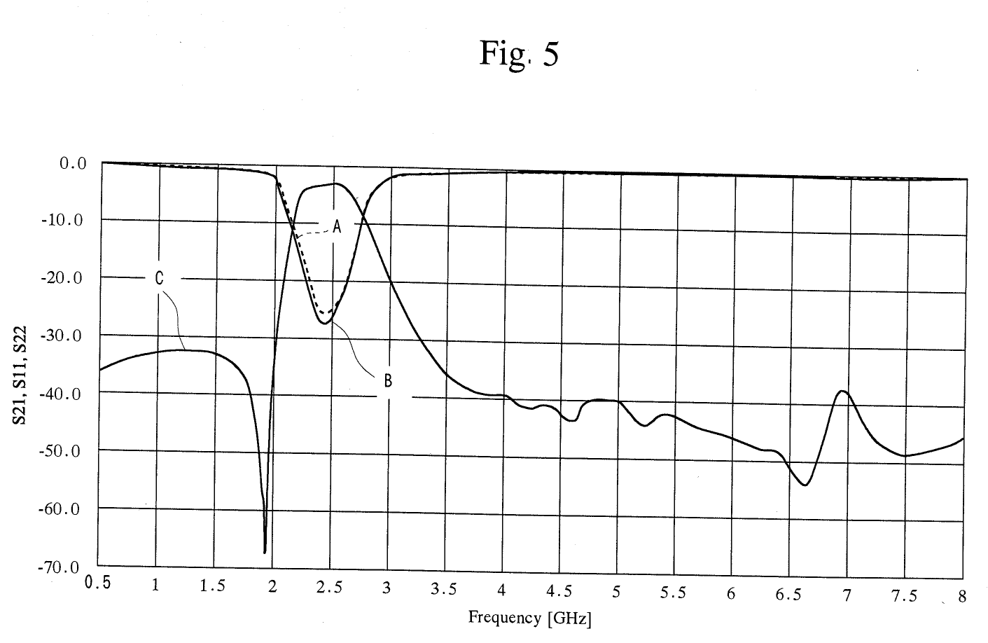

FIGS. 1 to 5 are drawings of a preferred embodiment of the present invention. FIG. 1 is a see-through perspective view of a multilayer filter of a preferred embodiment of the present invention. FIG. 2 is an exploded perspective view of the electrode construction of the multilayer filter of FIG. 1. FIG. 3 is an equivalent circuit diagram of the electrical circuit of the multilayer filter of FIG. 1. FIG. 4 is a plan view of the multilayer filter of FIG. 1. FIG. 5 includes plots of electrical characteristics of the multilayer filter of FIG. 1.

In the figures, multilayer filter 1 is constructed by providing strip line electrodes and capacitor electrodes in a plurality of layers in a device body 100 in the form of a rectangular block made of a low temperature co-fired ceramic (LTCC) (i.e. a dielectric body) and by connecting the electrodes in the different layers through via conductors at predetermined positions so that the dielectric body is between the different layers. Electrodes are disposed in surfaces and internal portions of the device body, that is, in the layers from the first layer in the upper most position to the eighth layer in the lowermost position.

An output terminal electrode 101 is provided in the first layer in the upper surface of the device body 100.

In the second layer, a GND plane electrode (ground plane electrode) 102 having substantially the same area as the device body upper surface is provided.

In the third layer, strip line electrodes 111 and 112 in loop form and an electrode 113 are provided. A strip line electrode 113a is formed as one end portion of the electrode 113. A rectangular capacitor electrode 113b is formed as another end portion of the electrode 113.

In the fourth layer, strip line electrodes 121, 122, and 123 in loop form and a rectangular capacitor electrode 124 are provided. The strip line electrode 121 is superposed on the strip line electrode 111 in the third layer, while the strip line electrode 122 is superposed on the strip line electrode 112 in the third layer. Furthermore, one end of the strip line electrode 121 is connected to one end of the strip line electrode 111 by a via conductor 125. One end of the strip line electrode 122 is connected to one end of the strip line electrode 112 by via conductor 126.

The strip line electrode 123 is superposed on the strip line electrode formed as one end portion of the electrode 113 in the third layer. One end of the strip line electrode 123 is connected to an open end of the strip line electrode formed as one end portion of the electrode 113 by a via conductor 127. The capacitor electrode 124 is superposed on the capacitor electrode formed as another end portion of the electrode 113. The capacitor electrode 124 has a projection at its one side. This projection is connected to the other end of the strip line electrode 112 in the third layer by a via conductor 128.

In the fifth layer, strip line electrodes 131 to 134 in loop form are provided. The strip line electrode 131 is superposed on the strip line electrode 121 in the fourth layer. One end of the strip line electrode 131 is connected to the other end of the strip line electrode 121 by via conductor 135. The strip line electrode 132 superposed on the strip line electrode 122 in the fourth layer. One end of the strip line electrode 132 is connected to the other end of the strip line electrode 122 by a via conductor 136.

The strip line electrode 133 is superposed on the strip line electrode 123 in the fourth layer. One end of the strip line electrode 133 is connected to the other end of the strip line electrode 123 by a via conductor 137. The strip line electrode 134 is disposed so as not to overlap any of the electrodes in the third and fourth layers. One end of the strip line electrode 134 is connected by a via conductor 138 to the output terminal electrode 101 in the first layer.

The sixth layer includes electrodes 141 and 142, a strip line electrode 144 in loop form and a rectangular capacitor electrode 143. A strip line electrode 141a is formed as one end portion of the electrode 141. A capacitor electrode 141b is formed as another end portion of the electrode 141. The strip line electrode 141a is superposed on the strip line electrode 131 in the fifth layer. An open end of the strip line electrode 141a is connected to the other end of the strip line electrode 131 by a via conductor 145.

A strip line electrode 142a is formed as one end portion of the electrode 142. A capacitor electrode 142b is formed as another end portion of the electrode 142. The strip line electrode 142a is superposed on the strip line electrode 132 in the fifth layer. An open end of the strip line electrode 142a is connected to the other end of the strip line electrode 132 by a via conductor 146.

The capacitor electrode 143 is superposed on the capacitor electrode 124 in the fourth layer. The capacitor electrode 143 has a projection at its one side. This projection is connected to the other end of the strip line electrode 111 in the third layer by a via conductor 147.

The strip line electrode 144 is superposed on the strip line electrode 134 in the fifth layer. One end of the strip line electrode 144 is connected to the other end of the strip line electrode 134 by a via conductor 148.

The seventh layer includes a GND electrode 151 and an electrode 152. A strip line electrode 152a in loop form is formed as one end portion of the electrode 152 so as to be superposed on the strip line electrode 144 in the sixth layer. An open end of the strip line electrode 152a is connected to the other end of the strip line electrode 144 in the sixth layer by a via conductor 153. A rectangular capacitor electrode 152b is formed as another end portion of the electrode 152 so as to be superposed on the capacitor electrode 143 in the sixth layer.

The eighth layer in the bottom surface of the device body 100 includes input terminal electrode 173, GND terminal electrodes 171, 172, dummy electrode 175 and a rectangular GND electrode 161 having projection 161a at its one side. The GND electrode 161 is connected to the GND electrode 151 in the seventh layer by a plurality of via conductors 162. Also, the projection 161a is connected to the GND plane electrode 102 in the second layer by via conductors 163. The input terminal electrode 173 is connected to the other end of the strip line electrode 133 of inductor 301 in the fifth layer by a via conductor 174.

An input terminal 201 in the equivalent circuit shown in FIG. 3, is formed by the input terminal electrode 173, while an output terminal 202 is formed by the output terminal electrode 101. An inductor 301 having one end connected to the input terminal 201 is formed by the strip line electrodes 133, 123, and 113a. An inductor 302 having one end connected to the output terminal 202 is formed by strip line electrodes 134, 144, and 152a.

A capacitor 401 connected in series between series inductor 301 and inductor 302 includes capacitor electrodes 113b and 124. The combination of series capacitors 402 and 403 includes capacitor electrodes 124 and 143. Series capacitor 404 is formed by the capacitor electrodes 143 and 152b.

Shunt inductor 303 having one end connected to a connection point between the capacitor 401 and the capacitor 402 is formed by the strip line electrodes 112, 122, 132, and 142a. Shunt capacitor 405 connected between the other end of the inductor 303 and GND terminal electrode 171 is formed by the capacitor electrode 142b and the GND electrode 151. Shunt inductor 304 having one end connected to a connection point between the capacitor 403 and the capacitor 404 is formed by the strip line electrodes 111, 121, 131, and 141a. Capacitor 406, connected between the other end of the inductor 303 and the GND terminal electrode 171, includes capacitor electrode 141 b and GND electrode 151.

As shown in FIG. 3, parasitic shunt capacitances 501 and 504 are produced as in the conventional arrangement of FIG. 11, and thus respectively correspond with capacitors C1P and C4P.

In the multilayer filter 1 having the above-described construction, first to fourth regions 11 to 14 are located on a predetermined plane in the device body 100, as shown in FIG. 4. Two or more of capacitors 401 to 404, connected in series between the ends of the inductors 301 and 302 opposite to the ends of the inductors connected to the input and output terminals 201 and 202, are stacked in the first region 11. The first inductor 301, at input terminal 201, is in the second region 12 adjacent to the first region 11. The second inductor 302, at output terminal 202, is in the third region 13 at a position such that the third region 13 and the second region 12 are symmetrical with respect to the first region 11, located between the third region 13 and the second region 12. Further, a first shunt branch formed by the series connection of inductor 303 and capacitor 405 and a second shunt branch formed by the series connection of inductor 304 and capacitor 406, respectively connected between ground points and the connection points between the capacitors 401 to 404, are in the fourth region 14 adjacent to the first to third regions 11 to 13.

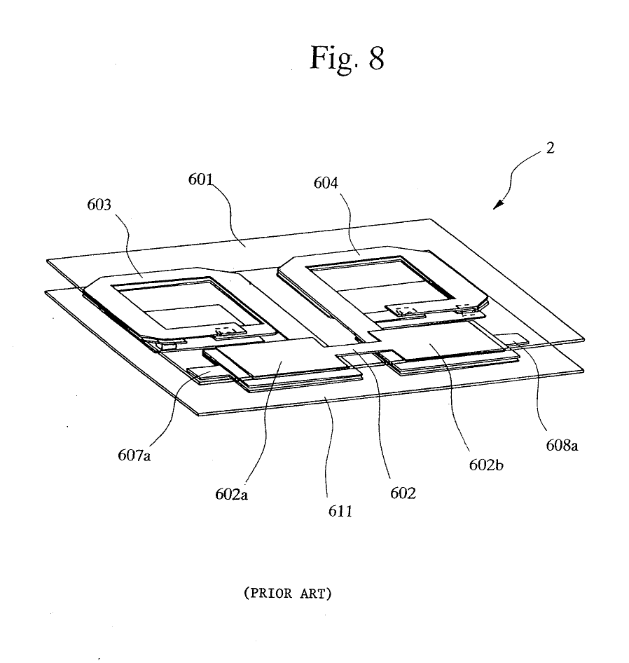

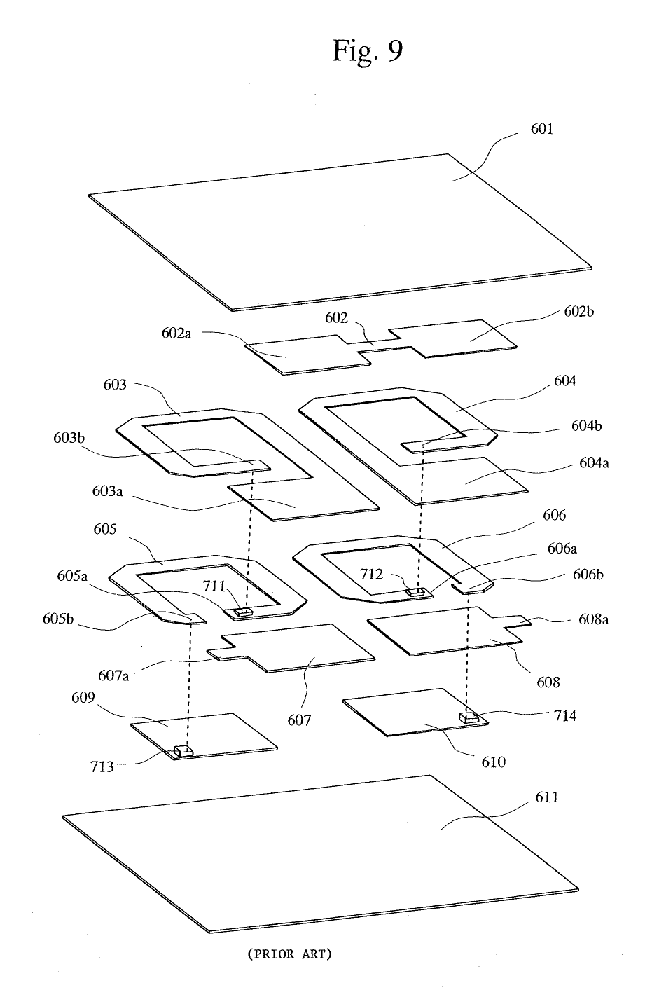

As described above, inductor 301 is connected in series between the input terminal 201 and series capacitor 401, and inductor is connected in series between the output terminal 202 and the capacitor 404, thereby obtaining effects (1) to (3) that are not achieved with the conventional arrangement of FIGS. 8-11.

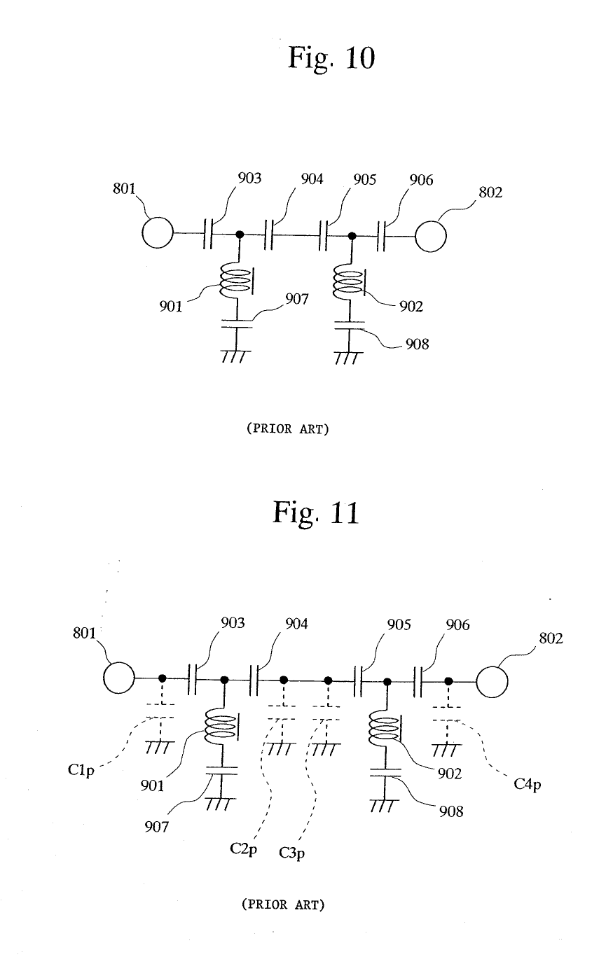

(1) The areas of the capacitor electrodes 113b, 124, 143, and 152b forming capacitors 401 and 404 for obtaining the same characteristics in the frequency pass band can be reduced. This effect is as explained below. If the capacitances of the capacitors 401 and 404 are C1 and C4, respectively, and the inductances of the inductors 301 and 302 are L1 and L2, respectively, the reactance of the filter in the desired frequency pass band becomes (1/ωC1)−ωL1 as a result of addition of the inductor 301 with respect to the negative reactance 1/ωC1* in the desired frequency pass band in the state before addition of the inductor 301. Therefore, a filter having equivalent frequency characteristics can be formed by using the capacitance C1 that is smaller than the capacitance C1*. Similarly, the negative reactance in the desired frequency pass band becomes (1/ωC4)−ωL4 as a result of addition of the inductor 302 with respect to the negative reactance 1/ωC4* in the desired frequency pass band in the state before addition of the inductor 302. Therefore, a filter having equivalent frequency characteristics can be formed by using the capacitance C4 that is smaller than the capacitance C4*. In the above expressions, C1* and C4* are the capacitances of the capacitors 903 and 906 of the prior art as illustrated in FIGS. 10 and 11, ω(=2πf, where f is frequency) is the angular frequency.

(2) The electrical coupling between the input terminal 201 and the output terminal 202 is reduced by series inductors 301 and 302 in the low frequency band that is attenuated by the filter. The amount of attenuation in the low frequency band is increased by series inductors 301 and 302. The reactance values of the inductors 301 and 302 become higher in proportion to frequency, while the reactances of the capacitors 401 and 404 become smaller as frequency increases since the reactances of the capacitors are inversely proportional to frequency. Therefore, a filter having frequency characteristics equivalent to those before addition of the inductors 301 and 302 can be formed by using the capacitances C1 and C4 having capacitance values lower than those of the capacitances C1* and C4* of the capacitors 401 and 404 before inductors 301 and 302 are added. Further, by using the capacitances C1 and C4 that are smaller than the capacitances C1* and C4* of capacitors 903 and 906 respectively, the values of the capacitances C1 and C4 are reduced in the low frequency band even under conditions including series inductors 301 and 302. In the high frequency band, in comparison with the pass band, the series impedance is increased due to the series connections of inductors 301 and 302 to suppress the passage of the high frequency energy. Since the attenuation in the high frequency band is large, as described above, use with W-LAN or Wi-MAX using a frequency higher than 3.0 GHz is effective.

(3) The shunt parasitic capacitances 501 and 504 that exist between ground and (1) the common connection of inductor 301 and capacitor 401 and (2) the common connection of inductor 302 and capacitor 404 are essentially unnecessary capacitances that are reduced in comparison with the arrangement wherein inductors 301 and 302 are not included. This is because, in impedance matching at the input and output terminals, the directions of the impedance vectors of the inductors 301 and 302 are opposite to the impedance vectors of the parasitic capacitances 501 and 504.

The frequency characteristics of the above-described multilayer filter are as shown in FIG. 5. In FIG. 5, the abscissa represents the frequency (GHz) and the ordinate represents the gain (dB). In FIG. 5, curve A represents the reflection characteristic at S11, curve B the reflection characteristic at S22, and curve C the pass characteristic at S21.

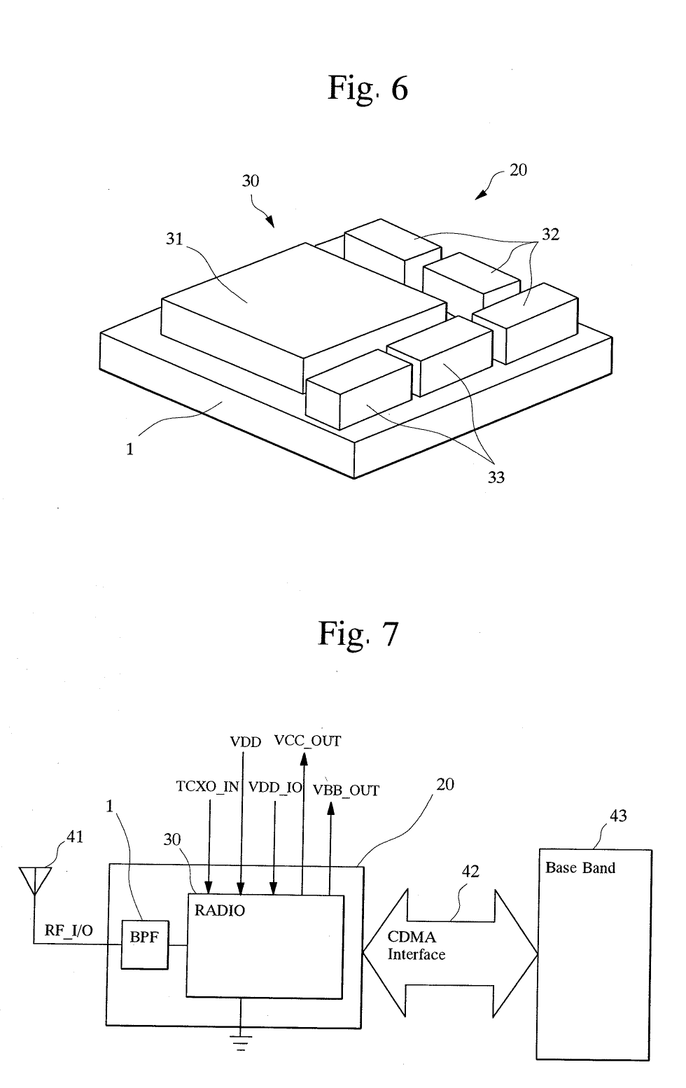

An electronic component can also be formed as a module by mounting an IC and other components on the surface of the above-described multilayer filter 1. For example, as shown in FIG. 6, an electronic component 20 in module form is formed by mounting on the LTCC substrate of the multilayer filter 1 a communication function unit 30 formed of an IC 31 having a wireless communication function and chip parts including capacitors 32 and resistors 33, and by connecting the multilayer filter 1 and the communication function unit 30.

Such an electronic component 20 can be used in a communication apparatus such as shown in FIG. 7. That is, an antenna 41 is connected to the multilayer bandpass filter 1 in the electronic component 20, and the communication function unit 30 is connected to an IC 43 for base band signal processing via a CDMA interface 42. A communication apparatus can be easily formed in this way.

The above-described embodiment is only an example of the present invention, and the present invention is not limited to the above-described embodiment.

### INDUSTRIAL APPLICABILITY

Inductors 301 and 302 are connected between input and output terminals 201 and 202 of a filter circuit and capacitors connected to the input and output terminals. A band pass filter having equivalent frequency characteristics while reducing the capacitances of the capacitors is formed in this way. The capacitances of the capacitors connected to the input and output terminals can be reduced in comparison with the conventional arrangement, thus enabling the device body to be reduced in size. Further, the parasitic capacitances produced in the conventional arrangement can be reduced by the inductors connected to the input and output terminals. As a result, the size of the multilayer filter can be reduced in comparison with the conventional art while substantially the same frequency characteristics are maintained.

1. A multilayer filter comprising filter circuit including a plurality of electrodes in a dielectric device body, first and second capacitors respectively disposed at input and output ends of the filter circuit, each of the capacitors having one end connected to one of two input/output terminals of the filter circuit, and inductors in the device body interposed between the input/output terminals and the one ends of the capacitors.

2. The multilayer filter according to claim 1, wherein the inductors include a winding.

3. The multilayer filter according to claim 1, wherein each of the inductors includes first and second ends and further comprising:
two or more further capacitors connected in series between the first ends of the inductors having the one ends respectively connected to the input/output terminals, and
a series circuit including an inductor and a capacitor connected between a ground point and a connection point between the further capacitors and one of the first and second capacitors.

4. The multilayer filter according to claim 3, wherein the two or more further capacitors connected in series between the other ends of the two inductors have the one ends respectively connected to the input/output terminals are stacked in a first region,
the first inductor connected to one of the input/output terminals is in a second region adjacent to the first region,
the second inductor connected to the other of the input/output terminals is in a third region existing in such a position that the third region and the second region being symmetrical with respect to the first region, the first region being located between the third region and the second region, and
the series circuit of the inductor and the capacitor connected between the ground point and the connection point between the further capacitors connected in series between the other ends of the inductors is in a fourth region adjacent to the first to third regions.

5. An electronic component comprising a module including mounting an IC mounted on the multilayer filter claim 1.

6. An electronic component comprising a module including an IC mounted on the multilayer filter of claim 2.

7. An electronic component comprising a module including an IC mounted on the multilayer filter of claim 3.

8. An electronic component comprising a module including an IC mounted on the multilayer filter of claim 4.

9. A multilayer band pass filter comprising:
a dielectric block carrying stacked layers including first, second, third, fourth, fifth, sixth and seventh layers, the dielectric block being interposed between each pair of the layers, each of the layers including planar electrically conducting elements,
the first, second and seventh layers including grounded planar electrically conducting elements electrically connected to each other by via conductors,
first and second terminals of the filter, the first and second terminals including planar electrical conducting elements respectively at first and second opposite ends of the stacked layers,
a first series inductor including winding segments in the fourth, fifth and sixth layers, the winding segments of the first series inductor including planar electrically conducting elements that are connected to each other by via conductors that are in the fourth, fifth and sixth layers, the winding segment in the fourth layer being connected by a via conductor to the first terminal,
a first series capacitor including the planar electrically conducting element in the sixth layer that is included in the first inductor and a planar electrically conducting element in the fifth layer,
a second series capacitor including the planar electrically conducting element in the fifth layer that is included in the first capacitor and a planar electrically conducting element in the third layer,
circuit elements connecting the planar electrically conducting element of the second series capacitor in the third layer to the second terminal,
a first shunt inductor including winding segments in the third, fourth, fifth and sixth layers, the winding segments of the first shunt inductor including planar electrically conducting elements that are connected to each other by via conductors and are in the third, fourth, fifth and sixth layers, the winding segment of the first shunt inductor in the sixth layer being connected by a via connector to the planar electrically conducting element of the first and second series capacitors in the fifth layer, and
a first shunt capacitor including the planar electrically conducting element of the first shunt inductor in third layer and the grounded planar electrically conducting element in the second layer.

10. The filter of claim 9 wherein the circuit elements connecting the planar electrically conducting element of the second series capacitor in the third layer to the planar electrically conducting element of the second terminal includes a third series capacitor, a second series inductor, a second shunt inductor and a second shunt capacitor,
the third series capacitor including the planar electrically conducting element of the second series capacitor in the third layer and an ungrounded planar electrically conducting element in the second layer,
the second shunt inductor including planar electrically conducting elements that are connected to each other by via conductors and are in the fourth, fifth and sixth layers, the planar electrical conductors of the first series inductor and the second shunt inductor in the fourth, fifth, and sixth layers differing from each other, the planar electrical conductor of the second shunt inductor in the third layer being included in the second shunt capacitor,
the second shunt capacitor further including the ground electrical conductor in the second layer,
the second series inductor including winding segments in the second, third and fourth layers, the winding segments of the second series inductor including planar electrically conducting elements that are connected to each other by via conductors and are in the third, fourth and fifth layers, the winding segment of the second series inductor in the fifth layer being connected by a via conductor to the first terminal.

11. The filter of claim 10 wherein the planar electrical conducting elements of the second and sixth layers include superfine and rectangular portions, the superfine portions in the second and sixth layers being respectively winding portions of the second and first series inductors, the rectangular winding portions in the second and sixth layers being respectively electrodes of the first and third series capacitors.

12. The filter of claim 11 wherein the positions of the rectangular and serpentine portions in the second and sixth layers are reversed from each other.

13. The filter of claim 12 wherein the serpentine portions include two substantially parallel legs;
the legs in the second layer being aligned with legs of the second series inductor in the third layer, one of the legs in each of second and third layers being aligned with a leg of the second series inductor in the fourth layer;
the legs in the sixth layer being aligned with legs of the first series inductor in the fifth layer, one of the legs in each of the fifth and sixth layers being aligned with a leg of the first inductor in the fourth layer.
